(19) United States
(12) Patent Application Publication
(10) Pub. No.: US 2017/0279067 A1
(43) Pub. Date: Sep. 28, 2017

(54) ORGANIC ELECTROLUMINESCENCE DISPLAY DEVICE

(71) Applicant: Japan Display Inc., Minato-ku (JP)

(72) Inventors: Takahiro Ushikubo, Minato-ku (JP); Hironori Toyoda, Minato-ku (JP)

(73) Assignee: Japan Display Inc., Minato-ku (JP)

(21) Appl. No.: 15/374,186

(22) Filed: Dec. 9, 2016

(30) Foreign Application Priority Data
Mar. 23, 2016 (JP) 2016-058847

(51) Int. Cl. H01L 51/50; H01L 51/52; H01L 51/00; H01L 27/32

(52) U.S. Cl. CPC H01L 51/5092; H01L 27/3244; H01L 51/5218; H01L 51/5234; H01L 51/504; H01L 51/5072; H01L 51/0097; H01L 2251/558; H01L 2251/5315; H01L 2251/308; H01L 2251/5338

(57) ABSTRACT

An organic EL display device includes an anode, a cathode and a light-emitting unit disposed between the anode and the cathode. The cathode is a transparent conductive film formed on the light-emitting unit. The light-emitting unit includes a light-emitting layer, an electron transport layer disposed between the light-emitting layer and the cathode, and an electron injection layer, disposed between the electron transport layer and the cathode, which is doped with an alkali metal. A thickness of the electron injection layer is equal to or greater than two times that of the electron transport layer.

### CROSS-REFERENCE TO RELATED APPLICATION

The present application claims priority from the Japanese Application JP2016-58847 filed on Mar. 23, 2016, the content of which is hereby incorporated by reference into this application.

### BACKGROUND OF THE INVENTION

1. Field of the Invention

The present invention relates to an organic EL display device.

2. Description of the Related Art

In a top-emission type organic EL display device, a transparent conductive film constituted of an indium zinc oxide (IZO) or the like is formed as a cathode on a light-emitting unit including a light-emitting layer (see JP 2009-295822 A). Such a transparent conductive film is generally formed by a sputtering method.

### SUMMARY OF THE INVENTION

Incidentally, in a light-emitting unit having a transparent conductive film formed thereon, the life span of a light-emitting layer may be short, and the inventors have found that the cause is because materials of the transparent conductive film are diffused inside the light-emitting unit during the formation of the transparent conductive film and the light-emitting layer is damaged.

The invention is contrived in view of the above problem, and an object thereof is to provide an organic EL display device capable of achieving an increase in the life span of a light-emitting layer.

An organic EL display device includes an anode, a cathode and a light-emitting unit disposed between the anode and the cathode. The cathode is a transparent conductive film formed on the light-emitting unit. The light-emitting unit includes a light-emitting layer, an electron transport layer disposed between the light-emitting layer and the cathode, and an electron injection layer, disposed between the electron transport layer and the cathode, which is doped with an alkali metal. A thickness of the electron injection layer is equal to or greater than two times that of the electron transport layer.

### BRIEF DESCRIPTION OF THE DRAWINGS

FIG. 1 is a diagram schematically illustrating a cross-section structure example of an organic EL display device according to an embodiment of the invention.

FIG. 2 is a diagram schematically illustrating a laminated structure example of an organic film included in the organic EL display device.

FIG. 3 is a diagram illustrating the current-voltage characteristics of the organic film.

FIG. 4 is a diagram illustrating transition of the luminance of a first light-emitting layer included in the organic film.

FIG. 5 is a diagram illustrating transition of the luminance of a second light-emitting layer included in the organic film.

FIG. 6 is a diagram illustrating transition of an increment of a voltage required for causing a predetermined current to flow to the organic film.

FIG. 7 is a diagram illustrating a relationship between the thickness of a second electron injection layer and the life span of the second light-emitting layer.

FIG. 8 is a diagram illustrating a relationship between the thickness of the second electron injection layer and a voltage required for causing a predetermined current to flow to the organic film.

### DETAILED DESCRIPTION OF THE INVENTION

Hereinafter, each embodiment of the invention will be described with reference the accompanying drawings. The disclosure is merely illustrative, and appropriate changes without departing from the spirit of the invention which can be readily conceived by those skilled in the art are naturally contained in the scope of the invention. In addition, in order to make the description clearer, the drawings may be schematically shown for the width, thickness, shape and the like of each unit as compared to the embodiment, but are merely illustrative, and are not intended to limit the interpretation of the invention. In addition, in the present specification and each drawing, the same components as those described in the previous drawings are denoted by the same reference numerals and signs, and thus the detailed description thereof may not be given.

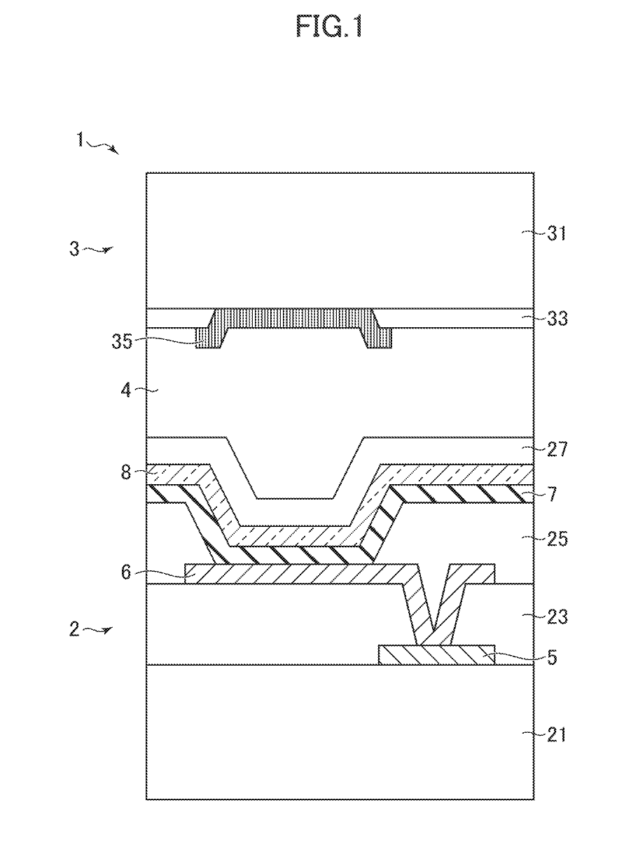

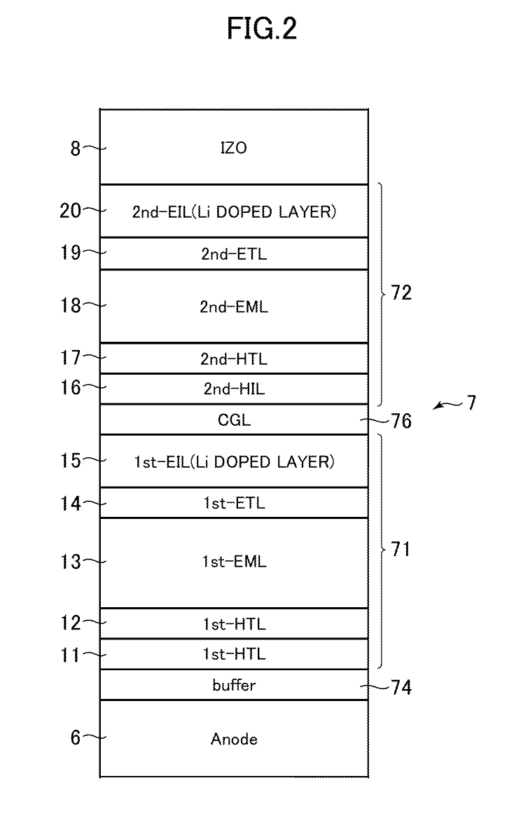

FIG. 1 is a diagram schematically illustrating a cross-section structure example of an organic EL display device 1 according to an embodiment of the invention. In the same drawing, hatching of insulating films 23 and 25 or the like is omitted in order to make the cross-section structures easier to understand. FIG. 2 is a diagram schematically illustrating a laminated structure example of an organic film 7 (organic EL element) included in the organic EL display device 1.

The organic EL display device 1 includes an array substrate 2 and an opposite substrate 3 which is opposite to the array substrate 2. The array substrate 2 and the opposite substrate 3 are bonded to each other with a filling material 4 interposed therebetween. In the organic EL display device 1, a top-emission type is adopted in which light is emitted in the direction of the opposite substrate 3 with respect to the array substrate 2. In the following description, the direction of the opposite substrate 3 with respect to the array substrate 2 is set to an upward direction.

The array substrate 2 is a laminate having an insulating film and a conductor layer laminated on a transparent substrate 21 constituted of a flexible resin such as, for example glass or polyimide A lower electrode 5 is, for example, an electrode connected to a TFT, not shown, for driving a pixel. The lower electrode 51 is formed of a conductive metal such as, for example, aluminum, silver, copper, nickel, or titanium.

The lower electrode 5 is covered with an insulating film 23. An anode 6 corresponding to each pixel is disposed on the insulating film 23. An opening for connecting the anode 6 to the lower electrode 5 is formed on the insulating film 23. The insulating film 23 is formed of an organic insulating material such as, for example, an acrylic resin, and the surface thereof is planarized. The anode 6 is formed of a conductive metal such as, for example, aluminum, silver, copper, nickel, or titanium, and has a reflecting surface.

The insulating film 23 and the anode 6 are covered with an insulating film 25. An opening having the anode 6 exposed to the bottom is formed in the insulating film 25. The insulating film 25 is also called a pixel separation film, a bank or a rib. The insulating film 25 is formed of a transparent organic material such as, for example, an acrylic resin. The anode 6 exposed to the bottom of the opening of the insulating film 25 is covered with the organic film 7 including a light-emitting layer. The details of the organic film 7 will be described later.

The organic film 7 is covered with a cathode 8. The cathode 8 is a transparent conductive film which is formed of a transparent conductive material such as, for example, an indium zinc oxide (IZO) or an indium tin oxide (ITO). The cathode 8 is covered with a sealing film 27. The sealing film 27 is formed of an inorganic insulating material such as, for example, a silicon oxide or a silicon nitride.

In the opposite substrate 3, a transparent substrate 31 constituted of a flexible resin such as, for example, glass or polyimide is provided with a black matrix 33 having an opening corresponding to each pixel formed therein and a color filter 35 filled into the opening. The opposite substrate 3 may not be provided.

As shown in FIG. 2, the organic film 7 includes a first light-emitting unit 71 and a second light-emitting unit 72. The first light-emitting unit 71 is disposed on a side close to the anode 6, and the second light-emitting unit 72 is disposed on a side close to the cathode 8. A buffer layer 74 is disposed between the anode 6 and the first light-emitting unit 71. A separation layer 76 is disposed between the first light-emitting unit 71 and the second light-emitting unit 72.

The first light-emitting unit 71 includes a first hole injection layer 11 (1st-HIL), a first hole transport layer 12 (1st-HTL), a first light-emitting layer 13 (1st-EML), a first electron transport layer 14 (1st-ETL), and a first electron injection layer 15 (1st-EIL), in order from the side close to the anode 6.

The second light-emitting unit 72 includes a second hole injection layer 16 (2nd-HIL), a second hole transport layer 17 (2nd-HTL), a second light-emitting layer 18 (2nd-EML), a second electron transport layer 19 (2nd-ETL), and a second electron injection layer 20 (2nd-EIL), in order from the side close to the anode 6.

In the present embodiment, the organic film 7 is provided with two light-emitting units 71 and 72, but the number of light-emitting units may be one. In addition, in the present embodiment, for example, the emission color of the first light-emitting layer 13 is yellow, the emission color of the second light-emitting layer 18 is blue, and the light-emitting layers are configured to emit white light as a whole, but the emission color is not limited thereto.

An example of materials of the first light-emitting layer 13 and the second light-emitting layer 18 which are capable of being used includes various emission materials of a fluorescent material such as Alq3 (tris(8-quinolinolato) aluminum), a phosphorescent material such as “tris(2-phenylpyridinato-N, C2′) iridium (III)”(Ir(ppy)3), “tris(1-phenylisoquinoline) iridium (III)” (Ir(piq)3), or “bis[2-(4′,6′-difluorophenyl) pyridinato-N, C2′] iridium (III) picolinate” (FIrpic), or the like.

An Example of materials of the first hole transport layer 12 and the second hole transport layer 17 which are capable of being used includes a material such as NPB(4,4′-bis[N-(1-naphthyl)-N-phenylamino] biphenyl) or TPD(N,N′-bis(3-methylphenyl)-N, N′-diphenyl-[1,1′-biphenyl]-4,4′-diamine).

An example of materials of the first electron transport layer 14 and the second electron transport layer 19 which are capable of being used includes a material such as Alq3 or BCP (bathocuproine).

An example of materials of the first electron injection layer 15 and the second electron injection layer 20 which are capable of being used includes an electron injection material doped with an alkali metal. An example of the electron injection material capable of being used includes an organic material such as Alq3 (tris(8-quinolinolato) aluminum) or BCP (bathocuproine). An example of the alkali metal to be exemplified includes Li, Na, K, Rb, Cs, or Fr.

The respective layers included in the organic film 7 are formed by, for example, a method such as a vacuum vapor deposition method, an application method, or a printing method. Further, the cathode 8 constituted of a transparent conductive material such as an indium zinc oxide (IZO) is formed on the second light-emitting unit 72 of the organic film 7, that is, on the second electron injection layer 20 by a sputtering method.

Hereinafter, more detailed contents of the present embodiment will be described.

Generally, in a case where a transparent conductive film such as an IZO is formed on a light-emitting unit by a sputtering method, the life span of a light-emitting layer included in the light-emitting unit may be short. The life span of the light-emitting layer is indicated by, for example, a time which will be taken until the luminance of light emitted by the light-emitting layer deteriorates to a predetermined level.

For example, in the laminated structure of FIG. 2, blue light emitted by the second light-emitting layer 18 of the second light-emitting unit 72 having the cathode 8 formed thereon deteriorates faster than yellow light emitted by the first light-emitting layer 13 of the first light-emitting unit 71, and thus there is a concern of a shift in color being caused as if white light is yellowish.

The inventors have found that the cause of the life span of alight-emitting layer being shortened is because, when a transparent conductive film such as an IZO is formed on a light-emitting unit by a sputtering method, indium (In) which is a material of the transparent conductive film is diffused inside the light-emitting unit and the light-emitting layer is damaged.

In order to suppress damage to the light-emitting layer due to such diffusion of indium (In), the inventors have come to realize an idea of making the distance between the transparent conductive film and the light-emitting layer larger than in the related art.

For example, in the laminated structure of FIG. 2, in a case where the distance between the cathode 8 and the second light-emitting layer 18 is made larger, the following three kinds are considered: increasing only the thickness of the second electron transport layer 19, increasing only the thickness of the second electron injection layer 20, and increasing both the thicknesses of the second electron transport layer 19 and the second electron injection layer 20.

However, increasing the thickness of a layer leads to an increase in electrical resistance, and eventually leads to an increase in power consumption. Therefore, there is also a problem in that the distance between the cathode 8 and the second light-emitting layer 18 is made larger in order to suppress damage to the second light-emitting layer 18, while an increase in electrical resistance is suppressed insofar as possible.

Consequently, in the present embodiment, the ratio of the thickness of the second electron injection layer 20 to the thickness of the second electron transport layer 19 is made relatively large. With such a configuration, it can be understood that the effect of being able to suppressing even an increase in electrical resistance while suppressing damage to the second light-emitting layer 18 is obtained. It is considered that this is because the second electron injection layer 20 is doped with an alkali metal such as Li, and the electrical resistance of the second electron injection layer 20 is smaller than that of the second electron transport layer 19.

Specifically, the thickness of the second electron injection layer 20 is preferably equal to or greater than two times that of the second electron transport layer 19, more preferably equal to or greater than 2.5 times, and is further more preferably equal to or greater than three times. With such a configuration, the effect can be obtained. On the other hand, even in a case where the second electron injection layer 20 is made excessively thick, the effect is saturated. Therefore, the thickness of the second electron injection layer 20 is preferably equal to or less than six times that of the second electron transport layer 19, and is more preferably equal to or less than five times.

In addition, the thickness of the second electron injection layer 20 is preferably equal to or greater than 35 nm, more preferably equal to or greater than 45 nm, and is further more preferably equal to or greater than 55 nm. With such a configuration, the effect can be obtained. On the other hand, even in a case where the second electron injection layer 20 is made excessively thick, the effect is saturated. Therefore, the thickness of the second electron injection layer 20 is preferably equal to or less than 120 nm, and is more preferably equal to or less than 100 nm.

In addition, the thickness of the second electron transport layer 19 is preferably equal to or less than 20 nm, more preferably equal to or less than 15 nm, and is further more preferably equal to or less than 10 nm. With such a configuration, the effect can be obtained. On the other hand, in order to exhibit the function of the second electron transport layer 19, the thickness of the second electron transport layer 19 is preferably equal to or greater than 5 nm.

The thicknesses of the second electron transport layer 19, the second electron injection layer 20 and the cathode 8 are determined on the basis of optical distances. Therefore, in a case where the thickness of the second electron injection layer 20 is increased, it is preferable to reduce the thickness of the cathode 8 accordingly. For this reason, in the present embodiment, the ratio of the thickness of the second electron injection layer 20 to the thickness of the cathode 8 is made relatively large.

Specifically, the thickness of the second electron injection layer 20 is preferably equal to or greater than one-eighth of that of the cathode 8, more preferably equal to or greater than one-sixth, and is further more preferably equal to or greater than one-fourth. With such a configuration, the effect can be obtained while suppressing the total thickness of the second electron injection layer 20 and the cathode 8. On the other hand, even in a case where the second electron injection layer 20 is made excessively thick, the effect is saturated. Therefore, the thickness of the second electron injection layer 20 is preferably equal to or less than one-half of the cathode 8, and is more preferably equal to or less than one-third.

In addition, the thickness of the cathode 8 is preferably equal to or less than 260 nm, more preferably equal to or less than 250 nm, and is further more preferably equal to or less than 240 nm. With such a configuration, the effect can be obtained. In addition, the time of formation of the cathode 8 can be shortened by making the cathode 8 relatively thin. On the other hand, in order to exhibit the function of the cathode 8, the thickness of the cathode 8 is preferably equal to or greater than 180 nm, and is more preferably equal to or greater than 200 nm.

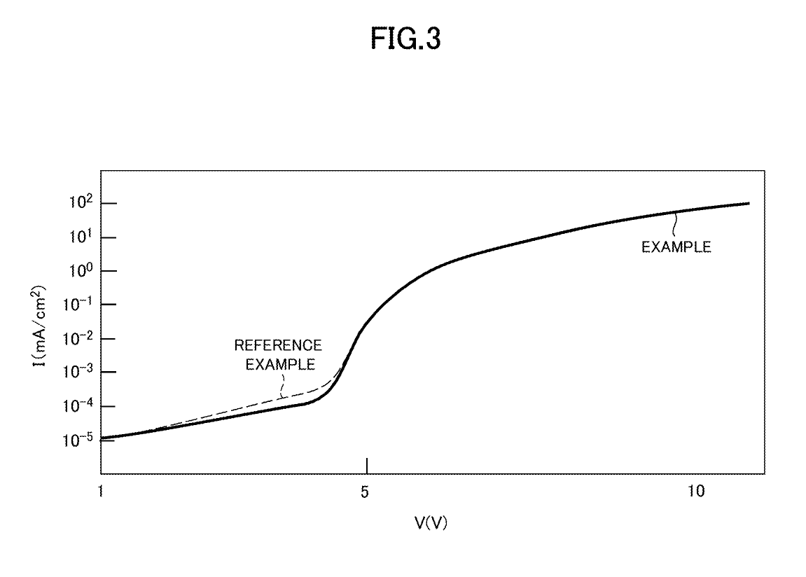

Hereinafter, an example and a reference example will be described with reference to FIGS. 3 to 8.

Here, in the example, the thickness of the cathode 8 is set to 240 nm, the thickness of the second electron injection layer 20 is set to 60 nm, and the thickness of the second electron transport layer 19 is set to 20 nm. On the other hand, in the reference example, the thickness of the cathode 8 is set to 280 nm, the thickness of the second electron injection layer 20 is set to 20 nm, and the thickness of the second electron transport layer 19 is set to 20 nm. The thicknesses of the respective layers other than these three layers are set to be the same as each other, and the materials of the respective layers are also set to be the same as each other. The second electron injection layer 20 having a thickness of 20 nm is sufficient to exhibit the electron injection function of the second electron injection layer 20.

FIG. 3 is a diagram illustrating the current-voltage (I-V) characteristics of the organic film 7. According to this, a current-voltage characteristic curve of the example and a current-voltage characteristic curve of the reference example are substantially the same as each other. Particularly, both the curves are substantially the same as each other in a range of 7 V to 9 V used in light emission. In the example, the second electron injection layer 20 is made thicker than in the reference example, but an increase in voltage due to this is not shown.

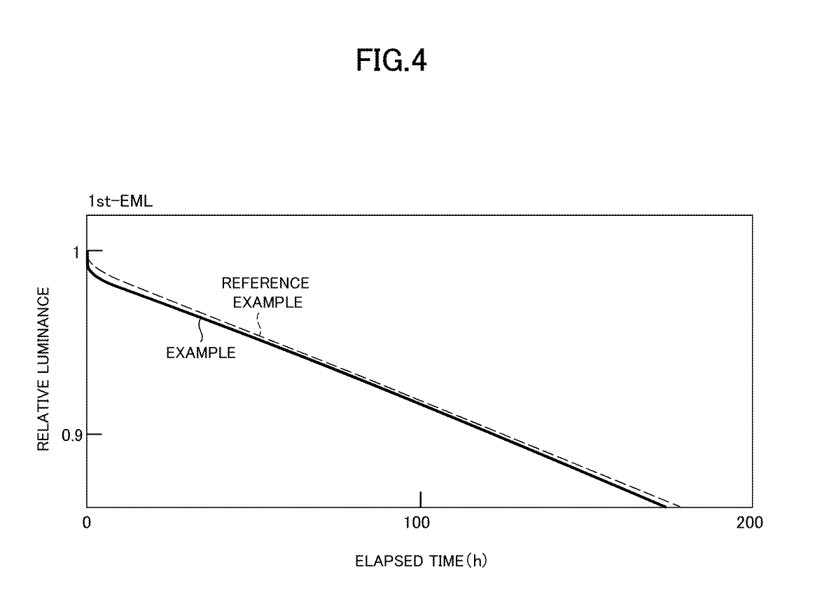

FIG. 4 is a diagram illustrating transition of the luminance of the first light-emitting layer 13 included in the organic film 7. The luminance of light emitted by the first light-emitting layer 13 is measured by, for example, spectroscopically dispersing light from the organic film 7, and extracting a component corresponding to the emission color (for example, yellow) of the first light-emitting layer 13. According to this, the rate of deterioration in luminance of the example and the rate of deterioration in luminance of the reference example are substantially the same as each other. It is considered that this is because, when the cathode 8 such as an IZO is formed on the organic film 7 by a sputtering method, indium (In) is not diffused to the first light-emitting layer 13, and damage does not occur in the first light-emitting layer 13.

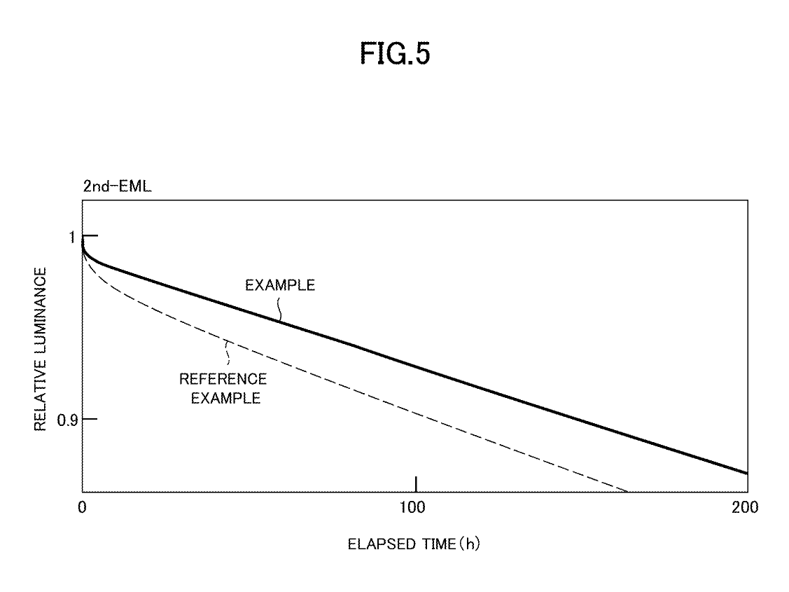

FIG. 5 is a diagram illustrating transition of the luminance of the second light-emitting layer 18 included in the organic film 7. The luminance of light emitted by the second light-emitting layer 18 is measured by, for example, spectroscopically dispersing light from the organic film 7, and extracting a component corresponding to the emission color (for example, blue) of the second light-emitting layer 18. According to this, the rate of deterioration in luminance of the example is gentler than the rate of deterioration in luminance of the reference example. That is, the deterioration in luminance is slower in the example than in the reference example. For example, in a case where times which will be taken until the luminance deteriorates to 95% are compared with each other, the time is 1.5 times longer in the example than in the reference example. It is considered that this is because, since the second electron injection layer 20 is thicker in the example than in the reference example, indium (In) is not likely to be diffused to the second light-emitting layer 18 and the second light-emitting layer 18 is not likely to be damaged, when the cathode 8 such as an IZO is formed on the organic film 7 by a sputtering method.

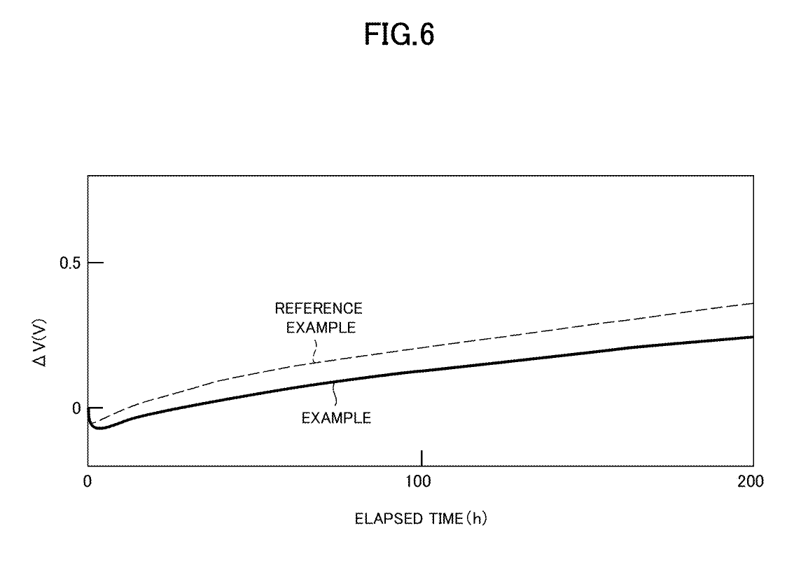

FIG. 6 is a diagram illustrating transition of an increment ΔV in a voltage required for causing a predetermined current to flow to the organic film 7. The predetermined current is, for example, 15 mA/cm2. According to this, an increment in a voltage of the example is smaller than an increment in a voltage of the reference example. That is, in the example, the voltage required for causing a predetermined current to flow does not increase as in the reference example. In other words, in the example, electrical resistance is smaller than in the reference example. It is considered that this is because, in the example the second electron transport layer 19 is not made thicker than in the reference example, an increase in electrical resistance is suppressed by increasing the thickness of the second electron injection layer 20 having small electrical resistance which is doped with an alkali metal such as Li, and in addition thereto, an increase in electrical resistance due to damage to the second light-emitting layer 18 is also suppressed by increasing the thickness of the second electron injection layer 20.

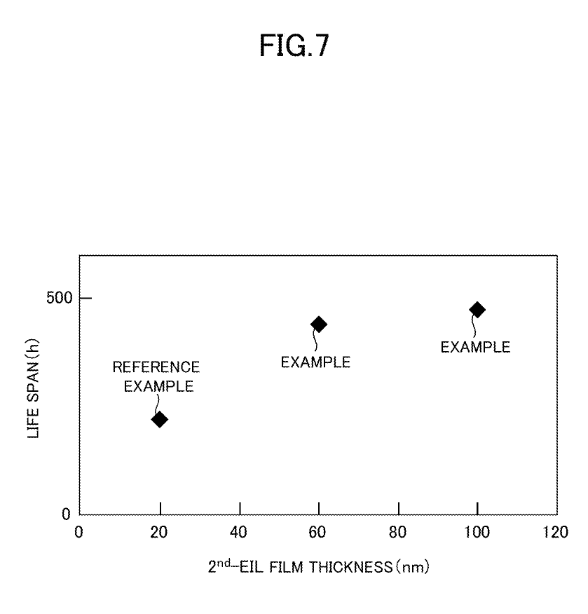

FIG. 7 is a diagram illustrating a relationship between the thickness of the second electron injection layer 20 and the life span of the second light-emitting layer 18. The thickness of the second electron injection layer 20 is 20 nm, 60 nm, and 100 nm. The life span of the second light-emitting layer 18 is set to, for example, a time which will be taken until luminance deteriorates to 95%. According to this, the life span is relatively short in a case where the thickness of the second electron injection layer 20 is 20 nm (reference example), and the life span is relatively long in a case of 60 nm and 100 nm (example). In addition, the life span increases in a case where the thickness of the second light-emitting layer 18 is 20 to 60 nm, and the life span is saturated in a case of 60 to 100 nm.

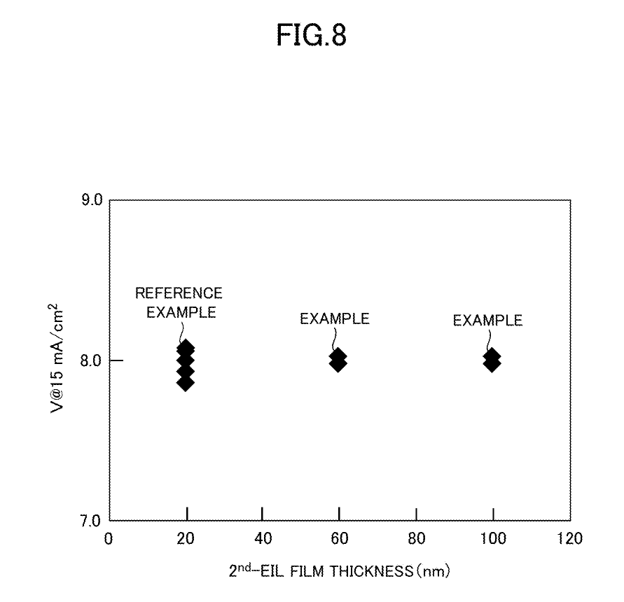

FIG. 8 is a diagram illustrating a relationship between the thickness of the second electron injection layer 20 and a voltage required for causing a predetermined current to flow to the organic film 7. In the same drawing, the voltage required for causing a predetermined current to flow to the organic film 7 is plotted at every predetermined time interval. The predetermined current is, for example, 15 mA/cm2. According to this, a change in voltage is relatively large in a case where the thickness of the second electron injection layer 20 is 20 nm (reference example), and a change in voltage is relatively small in a case of 60 nm and 100 nm (example).

It should be understood that various modifications and alterations can be conceived by those skilled in the art within the spirit of the invention, and that such modifications and alterations also belong to the scope of the invention. For example, those skilled in the art can appropriately modify each of the embodiments described above by addition, deletion or design change of components, or by addition, omission or condition change of processes, and such modifications are also encompassed within the scope of the invention as long as they fall within the spirit of the invention.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An organic EL display device comprising:
an anode;
a cathode; and
a light-emitting unit disposed between the anode and the cathode,
wherein the cathode is a transparent conductive film formed on the light-emitting unit,
the light-emitting unit includes
a light-emitting layer,
an electron transport layer disposed between the light-emitting layer and the cathode, and
an electron injection layer, disposed between the electron transport layer and the cathode, which is doped with an alkali metal, and
a thickness of the electron injection layer is equal to or greater than two times that of the electron transport layer.

2. The organic EL display device according to claim 1, wherein the thickness of the electron injection layer is equal to or greater than 35 nm.

3. The organic EL display device according to claim 1, wherein a thickness of the electron transport layer is equal to or less than 20 nm.

4. The organic EL display device according to claim 1, wherein the thickness of the electron injection layer is equal to or greater than one-eighth of that of the cathode.

5. An organic EL display device comprising:
an anode;
a cathode; and
a light-emitting unit disposed between the anode and the cathode,
wherein the cathode is a transparent conductive film formed on the light-emitting unit,
the light-emitting unit includes
a light-emitting layer, and
an electron injection layer, disposed between the light-emitting layer and the cathode, which is doped with an alkali metal, and
a thickness of the electron injection layer is equal to or greater than 35 nm.
